(19) United States
(12) Patent Application Publication
(10) Pub. No.: US 2026/0011616 A1
(43) Pub. Date: Jan. 8, 2026

(54) INTERCONNECT BOARD WITH ELECTRONIC COMPONENT EMBEDDED IN THERMALLY ENHANCED CAVITY SUBSTRATE

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 19/213,052

(22) Filed: May 20, 2025

Related U.S. Application Data
(60) Provisional application No. 63/668,609, filed on Jul. 8, 2024.

(51) Int. Cl. H01L 23/34; H01L 23/00; H01L 23/31; H01L 23/498

(52) U.S. Cl. CPC H01L 23/34; H01L 23/3107; H01L 23/49827; H01L 23/562

(57) ABSTRACT

An interconnect board includes a thermally enhanced cavity substrate, an electronic component, a crack-inhibiting dielectric layer and a circuitry layer. The cavity in the thermally enhanced cavity substrate is defined by a heat conduction surface of a first conductive island and inner surrounding sidewalls of a stress-relief resin layer. The thermally enhanced cavity substrate further includes electrically conductive posts as vertical electrical conduction channel. The electronic component in the cavity is attached onto the heat conduction surface and covered and laterally surrounded by the crack-inhibiting dielectric layer. The circuitry layer can provide electrical connections between the electronic component and the electrically conductive posts. For applications involving electrical components with high thermal demand (such as power chips), the first conductive island may further include a metallized segment in contact with the bottom surface of the electronic component to improve thermal management.

### CROSS REFERENCE TO RELATED APPLICATION

This application claims the benefit of the filing date of U.S. Provisional Application Ser. No. 63/668,609 filed Jul. 8, 2024. The entirety of said Provisional Application is incorporated herein by reference.

### FIELD OF THE INVENTION

The present invention relates to an interconnect board and, more particularly, to an interconnect board with an electronic component embedded in a thermally enhanced cavity substrate.

### DESCRIPTION OF RELATED ART

High-performance microprocessors and ASICs require substrates that offer high performance and reliability for signal interconnection. However, in conventional resin laminate substrates, the electroplated copper layer is prone to peeling under stringent operational conditions, making these substrates unreliable for practical use. In specific applications, ceramic materials like alumina or aluminum nitride are preferred for their desirable attributes, including excellent electrical insulation, robust mechanical strength, low coefficient of thermal expansion (CTE), and efficient thermal conductivity. Consequently, multi-layer ceramic substrates, such as HTCC (high temperature co-fired ceramic) or LTCC (low temperature co-fired ceramic), have been developed to meet specific application demands.

In addition to the resin laminate substrates and the multi-layer ceramic substrates mentioned above, copper lead frame substrates have emerged as another favored option. They offer distinct advantages such as high thermal conductivity, excellent electrical properties, and straightforward manufacturing processes. However, there remains a critical need for further improvement to address issues such as warpage, cracking, and other related problems. This pursuit of enhancement is pivotal in ensuring the continued advancement and reliability of high-performance semiconductor devices.

### SUMMARY OF THE INVENTION

An objective of the present invention is to provide an interconnect board configured with an electronic component embedded in a thermally enhanced cavity substrate and characterized by alleviated warpage and improved electrical and thermal performance. In the manufacture of the interconnect board, a crack-inhibiting dielectric frame is employed to provide a beneficial effect during the deposition of a stress-relief resin layer, minimizing warpage and improving structural reliability.

In accordance with the foregoing and other objectives, the present invention provides an interconnect board that includes electrically conductive posts, a first conductive island, a stress-relief resin layer, an electronic component, a crack-inhibiting dielectric layer and a circuitry layer. The first conductive island is spaced from the electrically conductive posts and has a heat conduction surface located at a level between top and bottom sides of the electrically conductive posts. The stress-relief resin layer laterally covers sidewalls of the electrically conductive posts and laterally surrounds a cavity defined above the heat conduction surface of the first conductive island. The electronic component is disposed within the cavity and superimposed over the heat conduction surface of the first conductive island. The crack-inhibiting dielectric layer covers the top sides of the electrically conductive posts and top surfaces of the first stress-relief resin layer and the electronic component and extends into remaining spaces within the cavity. The circuitry layer is disposed on the crack-inhibiting dielectric layer and electrically connected to the electronic component and the electrically conductive posts through conductive vias.

Also, the present invention provides a semiconductor assembly, in which one or more semiconductor devices are disposed above the crack-inhibiting dielectric layer and electrically connected to the circuitry layer of the above-mentioned interconnect board.

These and other features and advantages of the present invention will be further described and more readily apparent from the detailed description of the preferred embodiments which follows.

### BRIEF DESCRIPTION OF THE DRAWINGS

The detailed description of the preferred embodiments of the present invention can best be understood when read in conjunction with the following drawings, in which:

FIG. 1 is a cross-sectional view of an electrically and thermally conductive plate in accordance with the first embodiment of the present invention;

FIGS. 2 and 3 are cross-sectional and top perspective views, respectively, of the structure of FIG. 1 further provided with a crack-inhibiting dielectric frame in accordance with the first embodiment of the present invention;

FIGS. 4 and 5 are cross-sectional and top perspective views, respectively, of the structure of FIGS. 2 and 3 further provided with a stress-relief resin layer in accordance with the first embodiment of the present invention;

FIGS. 6 and 7 are cross-sectional and bottom perspective views, respectively, of the structure of FIGS. 4 and 5 further formed with electrically conductive posts and first and second conductive islands in accordance with the first embodiment of the present invention;

FIGS. 8 and 9 are cross-sectional and bottom perspective views, respectively, of the structure of FIGS. 6 and 7 further provided with an interfacial dielectric layer in accordance with the first embodiment of the present invention;

FIGS. 10 and 11 are cross-sectional and top perspective views, respectively, of the structure of FIGS. 8 and 9 further formed with cavities to finish the fabrication of a thermally enhanced cavity substrate in accordance with the first embodiment of the present invention;

FIG. 12 is a cross-sectional view of the structure of FIG. 10 further provided with electronic components in accordance with the first embodiment of the present invention;

FIG. 13 is a cross-sectional view of the structure of FIG. 12 further provided with a crack-inhibiting dielectric layer in accordance with the first embodiment of the present invention;

FIG. 14 is a cross-sectional view of the structure of FIG. 13 further formed with openings in accordance with the first embodiment of the present invention;

FIG. 15 is a cross-sectional view of the structure of FIG. 14 further provided with a circuitry layer to finish the fabrication of an interconnect board in accordance with the first embodiment of the present invention;

FIG. 16 is a cross-sectional view of the structure of FIG. 15 further provided with top and bottom solder masks in accordance with the first embodiment of the present invention;

FIG. 17 is a cross-sectional view of the structure of FIG. 16 further provided with semiconductor devices and heat spreaders to finish the fabrication of an embedded component assembly in accordance with the first embodiment of the present invention;

FIG. 18 is a cross-sectional view of another aspect of the embedded component assembly in accordance with the first embodiment of the present invention;

FIG. 19 is a cross-sectional view of another aspect of the interconnect board in accordance with the first embodiment of the present invention;

FIG. 20 is a cross-sectional view of the structure of FIG. 13 subjected to removal of selected portions of the first conductive islands in accordance with the second embodiment of the present invention;

FIG. 21 is a cross-sectional view of the structure of FIG. 20 subjected to removal of exposed portions of the adhesives in accordance with the second embodiment of the present invention;

FIG. 22 is a cross-sectional view of the structure of FIG. 21 further provided with a circuitry layer and metallized segments to finish the fabrication of an interconnect board in accordance with the second embodiment of the present invention;

FIG. 23 is a cross-sectional view of the structure of FIG. 22 further provided with a top solder mask in accordance with the second embodiment of the present invention;

FIG. 24 is a cross-sectional view of the structure of FIG. 23 further provided with semiconductor devices and heat spreaders to finish the fabrication of an embedded component assembly in accordance with the second embodiment of the present invention;

FIG. 25 is a cross-sectional view of the structure of FIG. 24 further provided with a thermally conductive and electrically insulating layer and a metal sheet in accordance with the second embodiment of the present invention;

FIG. 26 is a cross-sectional view of the structure of FIG. 25 further provided with a thermally conductive material and a heat sink in accordance with the second embodiment of the present invention;

FIG. 27 is a cross-sectional view of the structure of FIG. 12 further provided with crack-inhibiting dielectric layers from above and below, respectively, in accordance with the third embodiment of the present invention;

FIG. 28 is a cross-sectional view of the structure of FIG. 27 further formed with openings in accordance with the third embodiment of the present invention;

FIG. 29 is a cross-sectional view of the structure of FIG. 28 further provided with circuitry layers to finish the fabrication of an interconnect board in accordance with the third embodiment of the present invention; and

FIG. 30 is a cross-sectional view of another aspect of the interconnect board in accordance with the third embodiment of the present invention.

### DETAILED DESCRIPTION OF THE PREFERRED EMBODIMENTS

Hereafter, examples will be provided to illustrate the embodiments of the present invention. The advantages and effects of the invention will become more apparent from the following description of the present invention. It should be noted that the accompanying figures are simplified and illustrative. The quantity, shape and size of components shown in the figures may be modified according to practical conditions, and the arrangement of components may be more complex. Other various aspects may also be practiced or applied in the invention, and various modifications and variations can be made without departing from the spirit of the invention based on various concepts and applications.

### Embodiment 1

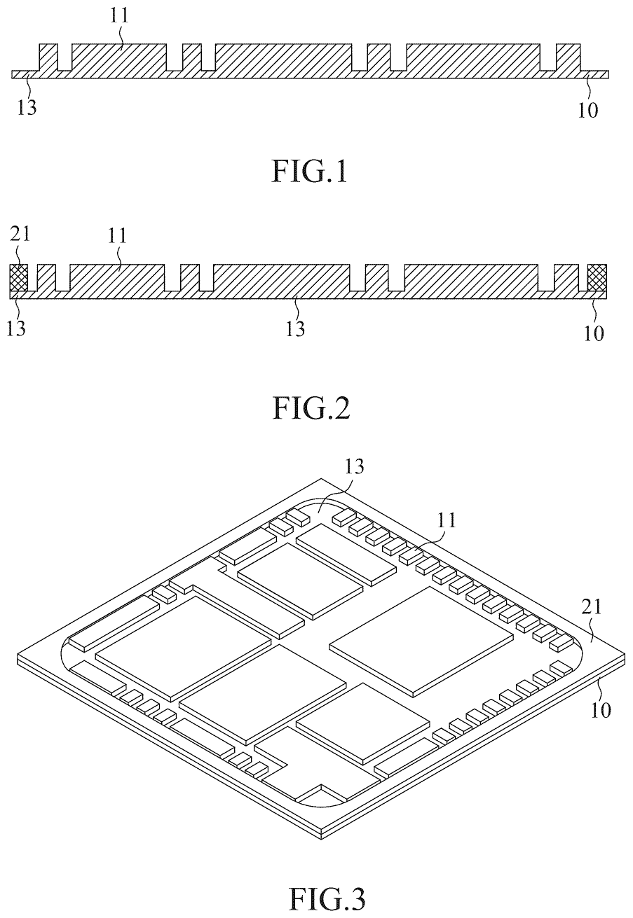

FIGS. 1-15 are schematic views showing a method of making an interconnect board that includes electrically conductive posts, first and second conductive islands, electronic components, a stress-relief resin layer, a crack-inhibiting dielectric layer and a circuitry layer in accordance with the first embodiment of the present invention.

FIG. 1 is a cross-sectional view of an electrically and thermally conductive plate 10 formed with an array of protrusions 11 projecting from an underlayer 13 by, for example, one-sided etching or plating. The electrically and thermally conductive plate 10 can have a thickness (namely, a combined thickness of the protrusion 11 and the underlayer 13) ranging from, for example, 0.15 mm to 0.5 mm, and typically is made of copper, aluminum, alloy 42, iron, nickel, silver, gold, combinations thereof, alloys thereof or any other suitable metals. In this embodiment, the electrically and thermally conductive plate 10 is made of copper with a thickness of about 0.25 mm, and the thickness of the underlayer 13 is illustrated as 0.05 micrometers.

FIGS. 2 and 3 are cross-sectional and top perspective views, respectively, of the structure provided with a crack-inhibiting dielectric frame 21. The crack-inhibiting dielectric frame 21 may have an elastic modulus lower than 50 Gpa and is deposited and attached on the underlayer 13 from above to define a compartment 20. In practice, the structure is typically manufactured in a multi-compartment form (not shown in the figures), which contains a plurality of separate compartments 20 defined by the crack-inhibiting dielectric frame 21. For instance, the compartments 20 may be arranged into an N×M array, such as a 2×2 array, and these protrusions 11 are present in the same quantity and arrangement within each compartment 20. Preferably, the crack-inhibiting dielectric frame 21 contains reinforcement to enhance the functionality of suppressing crack propagation through the crack-inhibiting dielectric frame 21. For instance, the crack-inhibiting dielectric frame 21 may be made of an organic material (such as epoxy-based material) with glass reinforcement (such as fiberglass). In this illustration, the top side of the crack-inhibiting dielectric frame 21 is substantially coplanar with the top sides of the protrusions 11. By using a crack-inhibiting dielectric frame 21 with an elastic modulus lower than 50 GPa, instead of a conventionally used metal frame, the structural warpage caused by the subsequent resin deposition process can be suppressed.

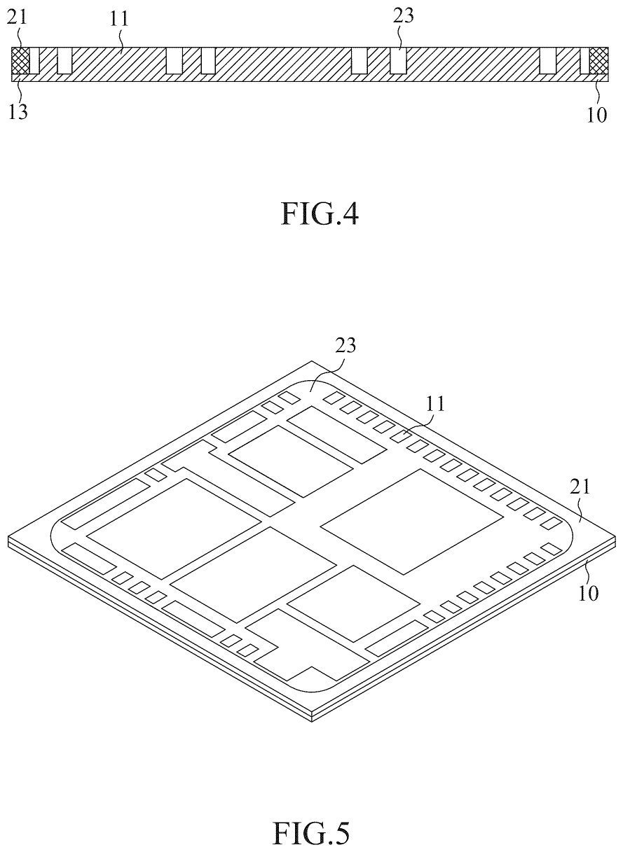

FIGS. 4 and 5 are cross-sectional and top perspective views, respectively, of the structure provided with a stress-relief resin layer 23. The stress-relief resin layer 23 is filled into remaining spaces within the compartment 20 to cover sidewalls of the protrusions 11 and the top surface of the underlayer 13 and an inner periphery of the crack-inhibiting dielectric frame 21. The capability of the stress-relief resin layer 23 to absorb stress helps further alleviate warpage. Preferably, the stress-relief resin layer 23 has an elastic modulus lower than that of the crack-inhibiting dielectric frame 21. For instance, the stress-relief resin layer 23 may have an elastic modulus lower than 30 Gpa. Additionally, the stress-relief resin layer 23 may contain electrically insulative fillers with a coefficient of thermal expansion (CTE) less than 20 ppm dispersed in an organic material (such as epoxy-based material). This facilitates the alleviation of internal expansion and shrinkage of the stress-relief resin layer 23 during thermal cycling, thereby restraining resin cracking. In this illustration, the top surface of the stress-relief resin layer 23 is substantially coplanar with the top sides of the protrusions 11 and the crack-inhibiting dielectric frame 21.

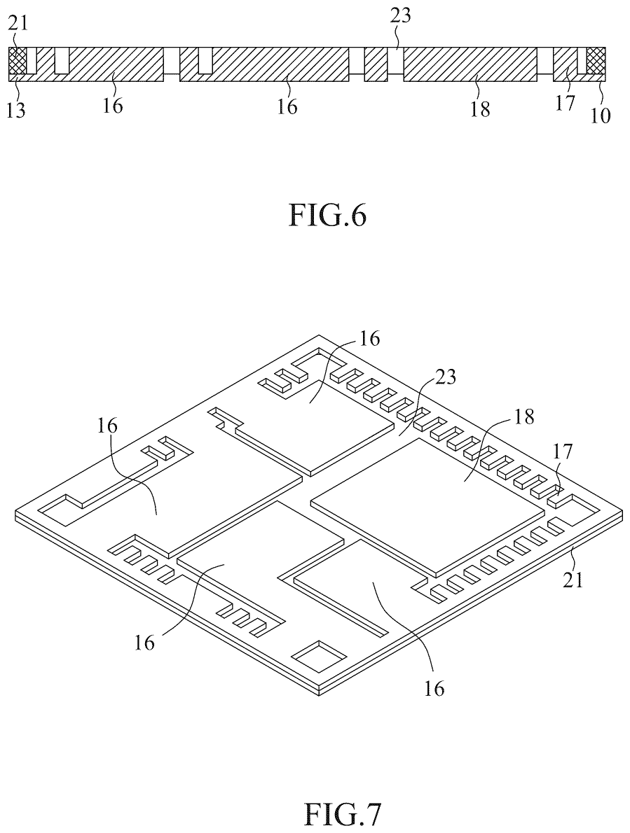

FIGS. 6 and 7 are cross-sectional and bottom perspective views, respectively, of the structure formed with one or more first conductive islands 16 (e.g. four first conductive islands illustrated in FIG. 7), electrically conductive posts 17 and optionally one or more second conductive islands 18 (e.g. one second conductive island illustrated in FIG. 7). The underlayer 13 of the electrically and thermally conductive plate 10 is patterned by, for example, etching, to leave selected portions of the underlayer 13 each integrated with a respective one of the protrusions 11. Accordingly, the first conductive islands 16, the electrically conductive posts 17 and the second conductive island 18 spaced from each other by gaps are formed, and selected portions of the stress-relief resin layer 23 are exposed from the gaps. The metal patterning techniques include wet etching, electro-chemical etching, laser-assisted etching, and their combinations with etch masks (not shown) thereon. Each of the first conductive islands 16, the electrically conductive posts 17 and the second conductive island 18 has upper sidewall portions laterally covered by and surrounded by the stress-relief resin layer 23 and lower sidewall portions laterally surrounded by the gaps.

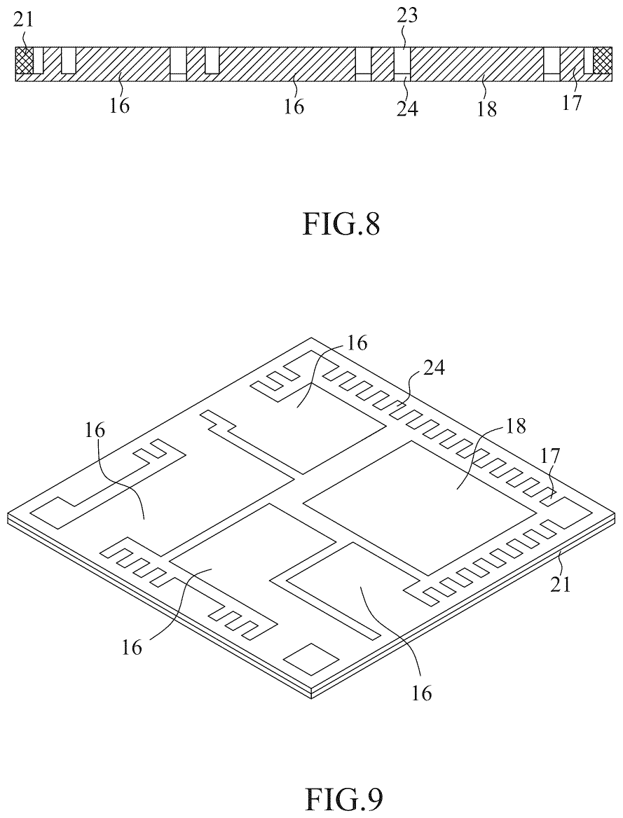

FIGS. 8 and 9 are cross-sectional and bottom perspective views, respectively, of the structure provided with an interfacial dielectric layer 24. Optionally, the interfacial dielectric layer 24 is filled into the gaps to cover the lower sidewall portions of the first and second conductive islands 16, 18 and the electrically connective posts 17. The interfacial dielectric layer 24 may be made of the same material as the stress-relief resin layer 23. In this illustration, the bottom surface of the interfacial dielectric layer 24 is substantially coplanar with the bottom sides of the first and second conductive islands 16, 18 and the electrically connective posts 17.

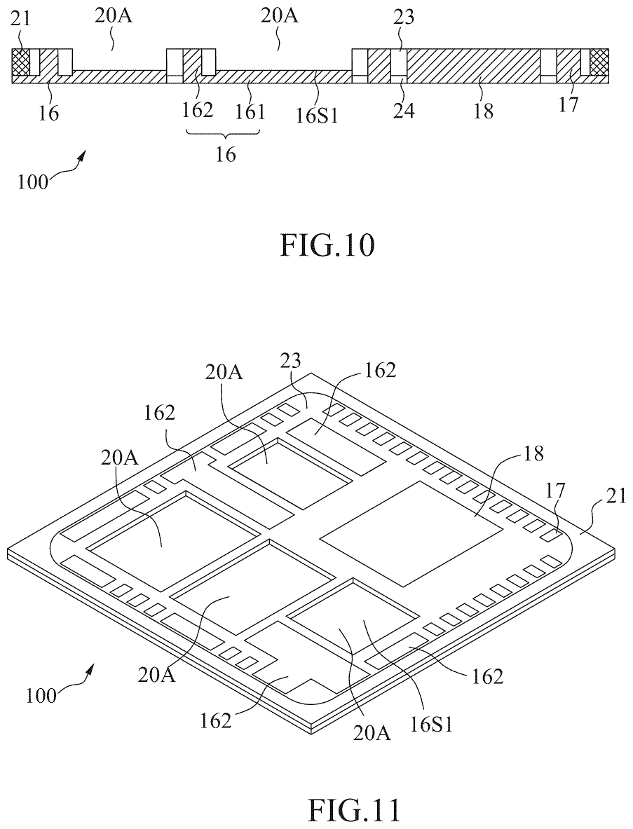

FIGS. 10 and 11 are cross-sectional and top perspective views, respectively, of the structure formed with one or more cavities 20A (e.g. four cavities as shown in FIG. 11). The first conductive islands 16 are partially removed by, for example, etching, from above to form the cavities 20A laterally surrounded by the stress-relief resin layer 23. In this illustration, the depth of the cavities 20A is less than the thickness of the stress-relief resin layer 23, and the stress-relief resin layer 23 has inner surrounding sidewalls exposed from the cavities 20A. As a result, each of the first conductive islands 16 has a recessed surface as a heat conduction surface 16S1 at a level between the top and bottom sides of the electrically conductive posts 17, and each of the cavities 20A is defined by the recessed surface of the respective first conductive island 16 as a bottom of the cavity 20A and the lateral surfaces of the stress-relief resin layer 23. More specifically, in this embodiment, each of the first conductive islands 16 includes a base segment 161 and a vertical segment 162 integrated with the base segment 161. The base segment 161 has a top surface as the heat conduction surface 16S1 and a bottom surface substantially coplanar with that of the stress-relief resin layer 23. The vertical segment 162 extends vertically from the base segment 161 beyond the heat conduction surface 16S1 of the base segment 161 and has a top surface substantially coplanar with that of the stress-relief resin layer 23.

At this stage, a thermally enhanced cavity substrate 100 is accomplished and includes the crack-inhibiting dielectric frame 21, the first and second conductive islands 16, 18, the electrically conductive posts 17, the stress-relief resin layer 23 and the interfacial dielectric layer 24.

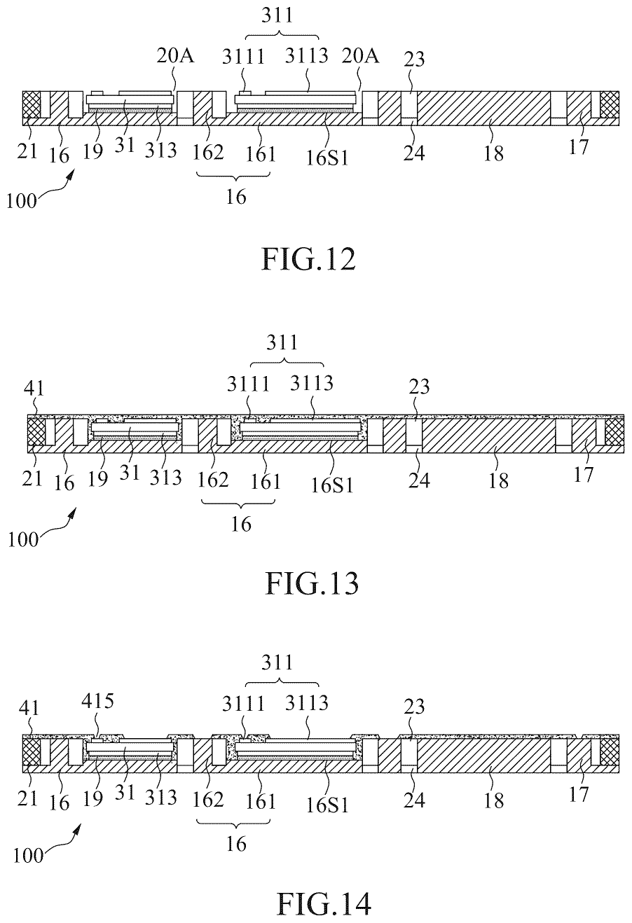

FIG. 12 is a cross-sectional view of the structure provided with electronic components 31 attached to the thermally enhanced cavity substrate 100 illustrated in FIG. 10. Each of the cavities 20A is occupied by one of the electronic components 31 which is mounted and superimposed over the heat conduction surface 16S1 of the respective first conductive island 16 by an adhesive 19. The electronic components 31 can be individually selected from either active components (such as transistors, diodes and the like) or passive components (such as capacitors, resistors, inductors and the like), depending on the design or function needed. In this embodiment, the electronic components 31 are illustrated as semiconductor devices each including a top electrode layer 311 and a bottom electrode layer 313, and the adhesive 19 exhibits electrical conductivity for electrical connection between the bottom electrode layer 313 of the electronic component 31 and the first conductive island 16. The top electrode layer 311 of the electronic component 31 includes a first contact pad 3111 and a second contact pad 3113. The bottom electrode layer 313 of the electronic component 31 is superimposed over and attached to the heat conduction surface 16S1 of the respective first conductive island 16 using the adhesive 19.

FIG. 13 is a cross-sectional view of the structure provided with a crack-inhibiting dielectric layer 41 on the thermally enhanced cavity substrate 100 and the electronic components 31 and into the cavities 20A. The crack-inhibiting dielectric layer 41 covers and contacts the thermally enhanced cavity substrate 100 and the electronic components 31 from above and fills into remaining spaces within the cavities 20A and conformally coats the peripheral edges of the electronic components 31 and the inner surrounding sidewalls of the stress-relief resin layer 23. The crack-inhibiting dielectric layer 41 may have an elastic modulus lower than 50 Gpa and preferably contains reinforcement to avoid crack propagation through the crack-inhibiting dielectric layer 41. For instance, the crack-inhibiting dielectric layer 41 may be made of an organic material (such as epoxy-based material) with glass reinforcement (such as fiberglass). The glass reinforcement can create a fiber-interlocking structure over the electronic components 31 and the thermally enhanced cavity substrate 100, while a portion of the organic material of the crack-inhibiting dielectric layer 41 further extends into the remaining space within the cavities 20A and between the electronic components 31 and the stress-relief resin layer 23.

FIG. 14 is a cross-sectional view of the structure provided with openings 415 to expose selected portions of the first conductive islands 16, the electrically conductive posts 17 and the top electrode layers 311 of the electronic components 31 from above. The openings 415 can be formed by numerous techniques including laser drilling, plasma etching and photolithography. Laser drilling can be enhanced by a pulsed laser. Alternatively, a scanning laser beam with a metal mask can be used. The openings 415 extend through the crack-inhibiting dielectric layer 41 and are aligned with the selected portions of the first conductive islands 16, the electrically conductive posts 17 and the top electrode layers 311 of the electronic components 31.

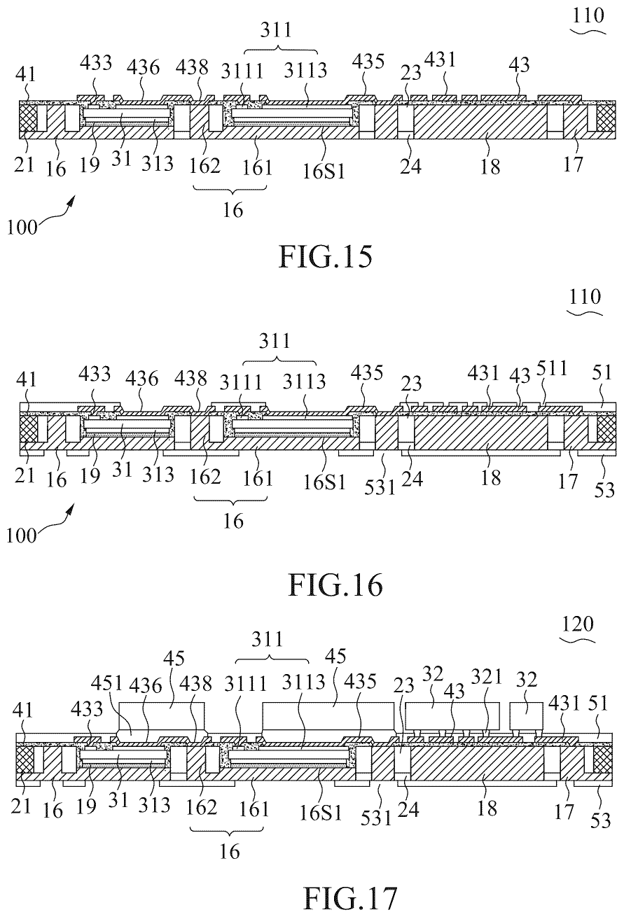

FIG. 15 is a cross-sectional view of the structure provided with a circuitry layer 43 on the crack-inhibiting dielectric layer 41 from above by metallization and metal patterning process. The circuitry layer 43 includes routing traces 431 and conductive paddles 435. The routing traces 431 include conductive vias 433 for electrical connection with the electrically conductive posts 17 and the electronic components 31. The conductive vias 433 extend through the crack-inhibiting dielectric layer 41 and contact the first contact pads 3111 of the top electrode layers 311 of the electronic components 31 and the electrically conductive posts 17. In this illustration, the routing traces 431 has selected portions superimposed over a top side of the second conductive island 18 to allow an external device to be mounted thereon as later described. Each of the conductive paddles 435 includes a first metallized recess 436 and/or a second metallized recess 438. The first metallized recess 436 extends through the crack-inhibiting dielectric layer 41 and contacts the second contact pad 3113 of the top electrode layer 311 of the electronic component 31. The second metallized recess 438 extends through the crack-inhibiting dielectric layer 41 and contacts the vertical segment 162 of the first conductive islands 16. As a result, the first metallized recess 436 can provide thermal conduction and electrical connection for the top electrode layer 311 of the electronic component 31, while the combination of the second metallized recesses 438 and the first conductive island 16 can provide thermal conduction and electrical connection for the bottom electrode layer 313 of the electronic component 31. Further, as shown, the first metallized recess 436 in contact with the top electrode layer 311 of the respective electronic component 31 attached to a respective one of the first conductive islands 16 can be integrated with the second metallized recess 438 in contact with another one of the first conductive islands 16 to provide an electrical connection between the top electrode layer 311 of one electronic component 31 and the bottom electrode layer 313 of another electronic component 31.

The metallization can be executed by numerous techniques, such as electroplating, electroless plating, evaporating, sputtering or their combinations, and typically by electroless plating followed by electroplating. The metal patterning techniques include wet etching, electro-chemical etching, laser-assisted etching, and their combinations with etch masks (not shown) thereon that define the circuitry layer 43.

At this stage, an interconnect board 110 is accomplished and includes the thermally enhanced cavity substrate 100, the electronic components 31 embedded in the cavities 20A of the thermally enhanced cavity substrate 100, the crack-inhibiting dielectric layer 41 on the electronic components 31 and the thermally enhanced cavity substrate 100, and the circuitry layer 43 thermally and electrically connected to the electronic components 31.

FIG. 16 is a cross-sectional view of the structure provided with a top layer of solder mask 51 and a bottom layer of solder mask 53. The top layer of solder mask 51 is deposited on the crack-inhibiting dielectric layer 41 as well as the circuitry layer 43 and has openings 511 to expose the selected portions of the routing traces 431 superimposed over the second conductive island 18 and the first and second metallized recesses 436 and 438 of the conductive paddles 435 from above. The bottom layer of solder mask 53 is deposited underneath the first and second conductive islands 16, 18 and the electrically conductive posts 17 as well as the interfacial dielectric layer 24 and has openings 531 to expose selected portions of the first conductive islands 16 and the electrically conductive posts 17 from below. Preferably, the exposed portions by the openings 511, 531 are further coated with electroless nickel/electroless palladium/immersion gold (ENEPIG).

FIG. 17 is a cross-sectional view of the structure provided with semiconductor devices 32 and heat spreaders 45 to finish the fabrication of an embedded component assembly 120. The semiconductor devices 32 are attached to and electrically connected to the circuitry layer 43 by first soldering materials 321 between the semiconductor devices 32 and the circuitry layer 43 and superimposed over the second conductive island 18. As a result, the semiconductor devices 32 can be electrically connected to the embedded electronic components 31 through the first soldering materials 321 and the circuitry layer 43. The heat spreaders 45 are attached to the conductive paddles 435 by second soldering materials 451 between the heat spreaders 45 and the first and second metallized recesses 436, 438 to allow thermal conduction between the heat spreaders 45 and the embedded electronic components 31. Accordingly, the first conductive islands 16 and the heat spreaders 45 can provide dual heat conduction channels for the embedded electronic components 31.

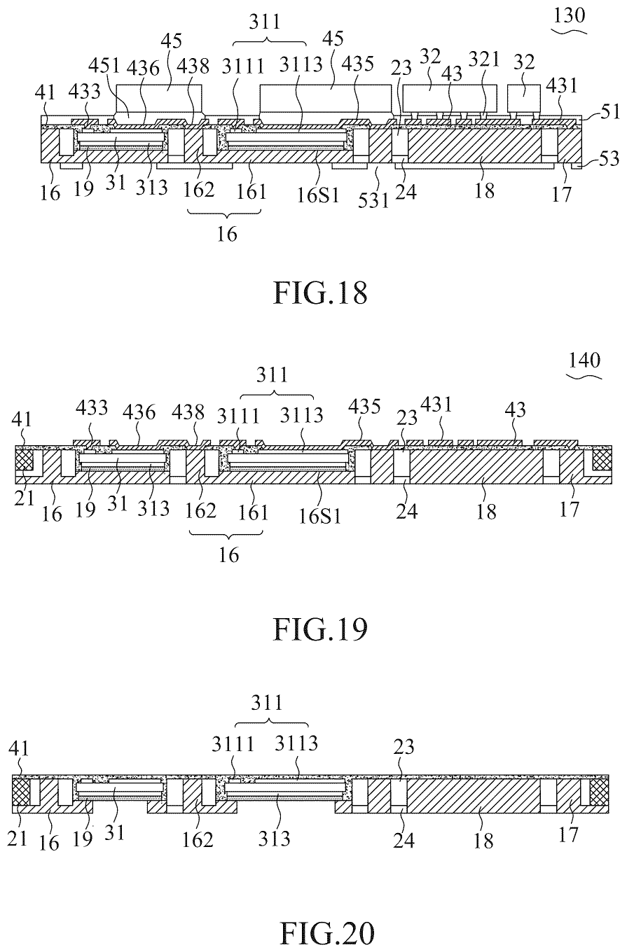

FIG. 18 is a cross-sectional view of another aspect of the embedded component assembly 130 in accordance with the first embodiment of the present invention. The embedded component assembly 130 is similar to that illustrated in FIG. 17, except that it is devoid of the crack-inhibiting dielectric frame. Although not explicitly depicted herein, it will be appreciated that when the assembly is manufactured in panel scale, a singulation process would be performed to obtain individual singulated assemblies, either with the crack-inhibiting dielectric frame 21 entirely removed, as illustrated in FIG. 18, or with a portion of the crack-inhibiting dielectric frame 21 retained.

FIG. 19 is a cross-sectional view of another aspect of the interconnect board 140 in accordance with the first embodiment of the present invention. The interconnect board 140 is similar to that illustrated in FIG. 15, except that the stress-relief resin layer 23 further extends below the crack-inhibiting dielectric frame 21. In this aspect, the crack-inhibiting dielectric frame 21 is attached on the electrically and thermally conductive plate 10 of FIG. 1 during deposition of the stress-relief resin layer 23. As a result, the stress-relief resin layer 23 provides mechanical bond between the bottom side of the crack-inhibiting dielectric frame 21 and the underlayer 13 of the electrically and thermally conductive plate 10.

### Embodiment 2

FIGS. 20-22 are cross-sectional views showing a method of making an interconnect board in accordance with the second embodiment of the present invention. For purposes of brevity, any description in above Embodiment 1 is incorporated herein insofar as the same is applicable, and the same description need not be repeated.

FIG. 20 is a cross-sectional view of the structure after removal of selected portions of the first conductive islands 16 from the structure of FIG. 13. The selected portions, located directly below the electronic components 31, of the first conductive islands 16 can be removed by, for example, etching to expose the adhesive 19 from below.

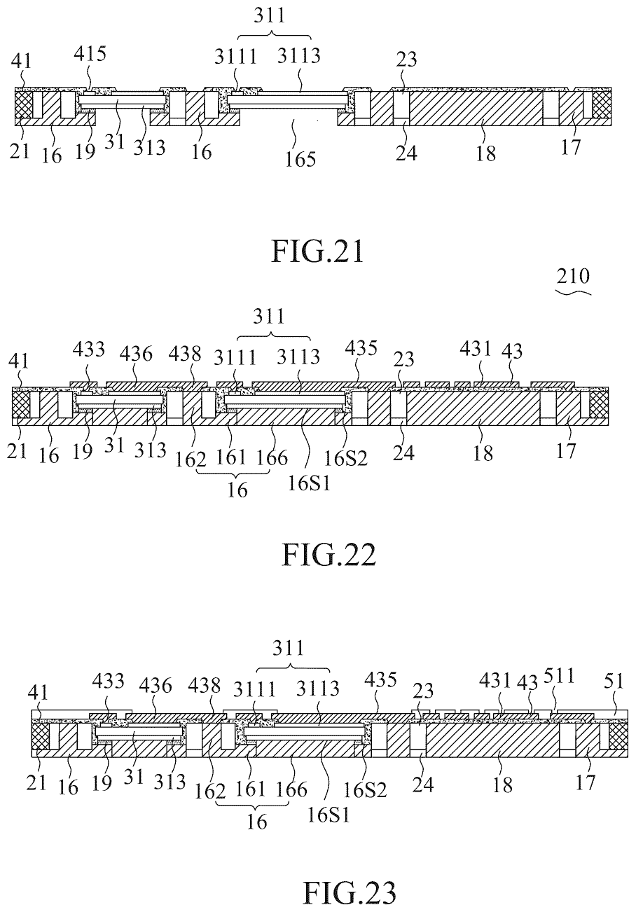

FIG. 21 is a cross-sectional view of the structure after removal of the exposed portions of the adhesive 19 and selected portions of the crack-inhibiting dielectric layer 41. The exposed portions of the adhesive 19 and the selected portions of the crack-inhibiting dielectric layer 41 can be removed by, for example, laser ablation. As a result, the bottom electrode layers 313 of the electronic components 31 are exposed from openings 165, while the top electrode layers 311 of the electronic components 31 and the electrically conductive posts 17 are exposed from openings 415.

FIG. 22 is a cross-sectional view of the structure provided with a circuitry layer 43 and metallized segments 166 to finish the fabrication of an interconnect board 210. The circuitry layer 43, formed by metallization and metal patterning, extends from the top electrode layers 311 of the electronic components 31 and the electrically conductive posts 17 in the upward direction, fills up the openings 415 to form conductive vias 433 and first and second metallized recesses 436, 438, and extend laterally on the crack-inhibiting dielectric layer 41. The metallized segments 166, formed by plating (typically by electroplating), extend from the bottom electrode layers 313 of the electronic components 31 in the downward direction, fill up the openings 165 and each have a bottom surface substantially coplanar with the bottom sides of the electrically conductive posts 17 and the second conductive island 18. As a result, each of the metallized segments 163 is integrated as a part of the respective first conductive island 16 and has a heat conduction surface 16S1 in direct contact with the bottom surface of the respective electronic component 31. In this embodiment, the base segment 161 has a remaining portion laterally surrounding and combined with the metallized segment 166 and has a recessed surface 16S2 located at a level below the heat conduction surface 16S1. The recessed surface 16S2 has a portion in contact with the stress-relief resin layer 23 and another portion attached to the bottom surface of the electronic component 31 by the remaining adhesive 19 between the recessed surface 16S2 of the first conductive island 16 and the bottom surface of the electronic component 31.

FIG. 23 is a cross-sectional view of the structure provided with a top layer of solder mask 51. The top layer of solder mask 51 has openings 511 to expose selected portions of the routing traces 431 superimposed over the second conductive island 18 and the first and second metallized recesses 436 and 438 of the conductive paddles 435 from above.

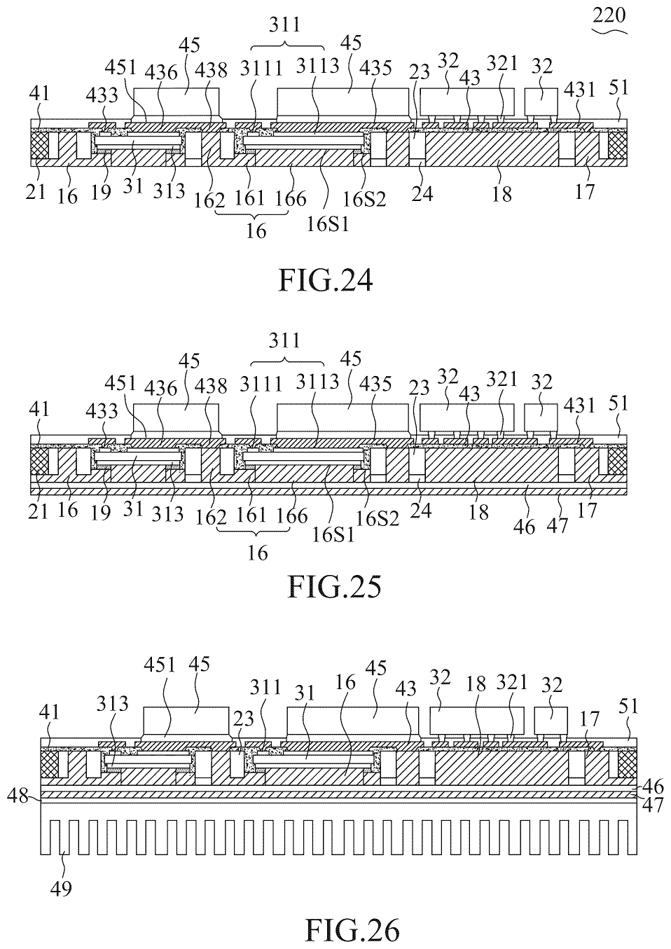

FIG. 24 is a cross-sectional view of the structure provided with semiconductor devices 32 and heat spreaders 45 to finish the fabrication of an embedded component assembly 220. The semiconductor devices 32 are electrically connected to the circuitry layer 43 by first soldering materials 321. The heat spreaders 45 are thermally connected to the first and second metallized recesses 436, 438 by second soldering materials 451.

FIG. 25 is a cross-sectional view of the structure provided with a thermally conductive and electrically insulating layer 46 and a metal sheet 47. The thermally conductive and electrically insulating layer 46 is sandwiched between the first conductive islands 16 and the metal sheet 47, between the electrically conductive posts 17 and the metal sheet 47, between the second conductive island 18 and the metal sheet 47, and between the interfacial dielectric layer 24 and the metal sheet 47.

FIG. 26 is a cross-sectional view of the structure provided with a thermally conductive material 48 and a heat sink 49. The thermally conductive material 48 is disposed between the metal sheet 47 and the heat sink 49 for heat transfer therebetween. Examples of the thermally conductive material 48 include thermal greases and pastes, phase-change materials (PCMs), thermal pads (elastomeric or graphite-based), solder-based thermally interfacial materials (e.g. metallic TIMs, liquid metal alloys) and the like. For SiC-based inverter and power module applications, solder-based TIMs or high-performance PCMs are preferred due to their high thermal conductivity and reliability.

### Embodiment 3

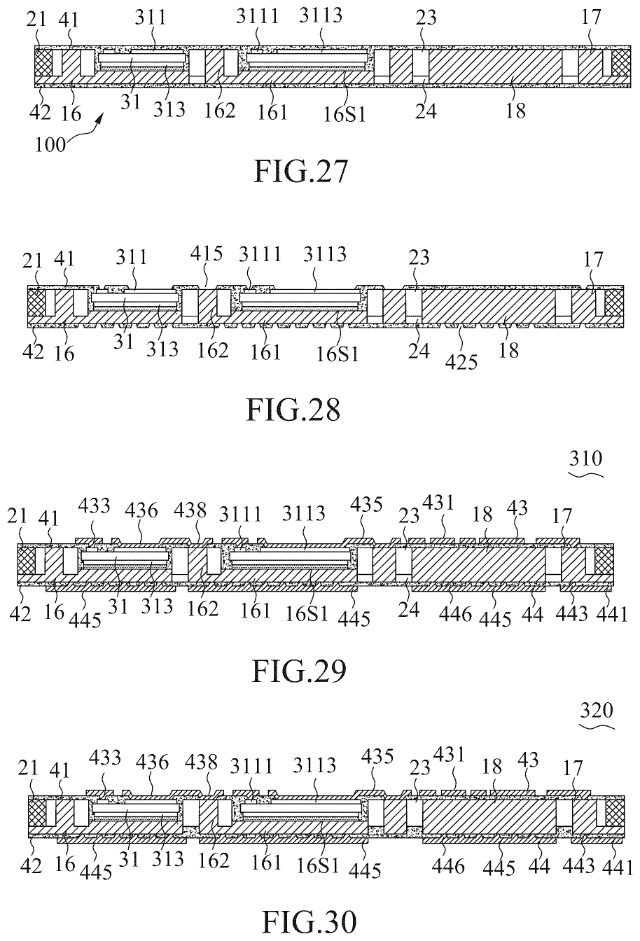

FIGS. 27-29 are cross-sectional views showing a method of making an interconnect board in accordance with the third embodiment of the present invention. For purposes of brevity, any description in above Embodiments 1 and 2 is incorporated herein insofar as the same is applicable, and the same description need not be repeated.

FIG. 27 is a cross-sectional view of the structure of FIG. 12 provided with crack-inhibiting dielectric layers 41 and 42 from above and below, respectively. The crack-inhibiting dielectric layer 41 covers and contacts the thermally enhanced cavity substrate 100 and the electronic components 31 from above and fills into remaining spaces within the cavities 20A and conformally coats the peripheral edges of the electronic components 31 and the inner surrounding sidewalls of the stress-relief resin layer 23. The crack-inhibiting dielectric layer 42 covers and contacts the thermally enhanced cavity substrate 100 from below. The symmetric deposition of the crack-inhibiting dielectric layers 41 and 42 is beneficial for further suppressing warpage.

FIG. 28 is a cross-sectional view of the structure formed with openings 415 in the crack-inhibiting dielectric layer 41 and openings 425 in the crack-inhibiting dielectric layer 42. The openings 415 extend through the crack-inhibiting dielectric layer 41 and are aligned with selected portions of the first conductive islands 16, the electrically conductive posts 17 and the top electrode layers 311 of the electronic components 31. The openings 425 extend through the crack-inhibiting dielectric layer 42 and are aligned with selected portions of the first conductive islands 16, the electrically conductive posts 17 and the second conductive island 18.

FIG. 29 is a cross-sectional view of the structure provided with circuitry layers 43 and 44 from above and below, respectively, to finish the fabrication of an interconnect board 310. The circuitry layer 43 includes routing traces 431 and conductive paddles 435. The routing traces 431 are electrically connected to the electrically conductive posts 17 and the electronic components 31 through conductive vias 433. The conductive paddles 435 are electrically and thermally connected to electronic components 31 and the first conductive islands 16 through first metallized recesses 436 and second metallized recesses 438. Likewise, the circuitry layer 44 includes routing traces 441 and conductive paddles 445. The routing traces 441 are electrically connected to the electrically conductive posts 17 through conductive vias 443. The conductive paddles 445 are electrically and thermally connected to the first conductive islands 16 and the second conductive island 18 through metallized vias 446.

FIG. 30 is a cross-sectional view of another aspect of the interconnect board 320 in accordance with the third embodiment of the present invention. The interconnect board 320 is similar to that illustrated in FIG. 29, except that no interfacial dielectric layer is present to fill the gaps among the first and second conductive islands 16 and 18 and the electrically conductive posts 17, and the crack-inhibiting dielectric layer 42 further extends into the gaps. As a result, the lower sidewall portions of the first and second conductive islands 16 and 18 and the electrically conductive posts 17 are conformally coated and covered by the crack-inhibiting dielectric layer 42.

The thermally enhanced cavity substrates, interconnect boards and assemblies described above are merely exemplary. Numerous other embodiments are contemplated. In addition, the embodiments described above can be mixed-and-matched with one another and with other embodiments depending on design and reliability considerations. The electronic component can share or not share the first conductive island with other electronic components. For instance, a first conductive island can accommodate a single electronic component, or numerous electronic components can be mounted over a single first conductive island.

As illustrated in the aforementioned embodiments, a distinctive interconnect board is configured to exhibit improved reliability and thermal and electrical performance. The interconnect board mainly includes electrically conductive posts, a first conductive island, a stress-relief resin layer, an electronic component, a crack-inhibiting dielectric layer, a circuitry layer, optionally an interfacial dielectric layer and optionally a second conductive island. In practice, an un-singulated interconnect board may first be manufactured at panel scale with a plurality of unit interconnect boards partitioned by a crack-inhibiting dielectric frame and then subjected to a singulation process to obtain a plurality of singulated interconnect boards. In the singulated interconnect board, the crack-inhibiting dielectric frame may either be partially retained or entirely removed during the singulation process. As a result, the interconnect board may optionally further include a singulated form of the crack-inhibiting dielectric frame. The crack-inhibiting dielectric frame in its singulated form can have at least one inner periphery each located around a compartment, and the electrically conductive posts, the first and second conductive islands, the stress-relief resin layer and the electronic component are accommodated in the compartment.

The stress-relief resin layer laterally surrounds a cavity defined above a heat conduction surface of the first conductive island, and laterally covers and contacts and conformally coats sidewalls of the electrically conductive posts and the optional second conductive island as well as the inner periphery of the crack-inhibiting dielectric frame. In one or more embodiments, the stress-relief resin layer laterally covers and contacts and conformally coats upper portions of the sidewalls of the electrically conductive posts and the optional second conductive island, while the optional interfacial dielectric layer laterally covers and contacts and conformally coats lower portions of the sidewalls of the electrically conductive posts and the optional second conductive island as well as sidewalls of the first conductive island. Typically, the stress-relief resin layer is made of a different material than the crack-inhibiting dielectric frame, and may be composed of an organic material incorporating electrically insulative fillers with low coefficients of thermal expansion (CTE) to alleviate internal expansion and shrinkage of the stress-relief resin layer during thermal cycling. The electrically insulative fillers may have CTE less than 20 ppm. Further, to absorb stress during resin deposition, the stress-relief resin layer may have an elastic modulus lower than that of the crack-inhibiting dielectric frame. Also, when the elastic modulus of the stress-relief resin layer is lower than that of the crack-inhibiting dielectric layer, the stress-relief resin layer can relieve any stress induced by the subsequent deposition of the crack-inhibiting dielectric layer. In some instances, the elastic modulus of the stress-relief resin layer is lower than 30 Gpa. The optional interfacial dielectric layer is located underneath the stress-relief resin layer and may be made of the same material as the stress-relief resin layer.

The electrically conductive posts, the first conductive island and the optional second conductive island are spaced apart from each other and may be formed collectively by metal etching. The electrically conductive posts can provide vertical electrical conduction, and typically have top sides substantially coplanar with the top surface of the stress-relief resin layer. The first conductive island and the optional second conductive island can offer locally high heat conduction channels for the electronic component embedded in the cavity and the semiconductor device electrically connected to the circuitry layer, respectively.

The first conductive island has a heat conduction surface located at a level between the top and bottom sides of the electrically conductive posts. For the electronic component with top and bottom electrode layers at its respective surfaces, the first conductive island not only can offer heat conduction channel for the electronic component, but also can be used for electrical connection with the bottom electrode layer of the electronic component. More specifically, the first conductive island can include a base segment and a vertical segment extending upwardly from the base segment and conformally coated by the stress-relief resin layer. The base segment can have a recessed surface located at a level below the electronic component, while the vertical segment has a top side located at a level above the recessed surface to allow electrical connection with the circuitry layer. The top side of the vertical segment may be substantially coplanar with the top sides of the electrically conductive posts. In accordance with the first aspect of the interconnect board, the recessed surface of the first conductive island can serve as the heat conduction surface attached to the bottom surface of the electronic component using an adhesive between the recessed surface and the bottom surface of the electronic component. When an electrical connection is required between the bottom electrode layer of the embedded electronic component and the recessed surface of the first conductive island, an electrically conductive adhesive is used. Given that the adhesive generally has limited thermal conductivity, the electronic component in the first aspect of the interconnect board is preferably a logic chip, a passive component, or any component with lower thermal demand so as to minimize thermal management issues.

For applications involving electrical components with high thermal demand (such as power chips), the second aspect of the interconnect board introduces a further enhancement, where the first conductive island further includes a metallized segment that has the heat conduction surface in contact with the bottom surface of the electronic component. The metallized segment can be formed through plating (typically electroplating) on the bottom electrode layer of the electronic component and integrated as a part of the first conductive island. For instance, in one or more embodiments, the metallized segment is electroplated in an opening of the base segment and integrated with the base segment. The bottom surfaces of the metallized segment and the base segment can be substantially coplanar with the bottom sides of the electrically conductive posts and the optional second conductive island as well as the bottom surface of the optional interfacial dielectric layer. The recessed surface of the base segment is located below the heat conduction surface of the metallized segment and may have a portion covered by the stress-relief resin layer and optionally another portion covered by the adhesive in contact with the bottom surface of the electronic component. As such, the upper sidewalls of the metallized segment may be laterally surrounded by the stress-relief resin layer and the adhesive.

The crack-inhibiting dielectric layer can serve as an electrically insulating spacer on the electronic component, the first and second conductive islands and the electrically conductive posts and provide a reliable platform for circuitry deposition thereon. In one or more embodiments, the crack-inhibiting dielectric layer fills up spaces within the cavity above the heat conduction surface of the first conductive island and conformally coats and contacts inner surrounding sidewalls of the stress-relief resin layer and peripheral edges of the electronic component. Preferably, the crack-inhibiting dielectric layer is made from a filler-free organic material to prevent filler particles from contributing to the layer's susceptibility to cracking. More preferably, the crack-inhibiting dielectric layer is made of an organic material containing reinforcement configured to suppress crack propagation.

The circuitry layer is disposed on the crack-inhibiting dielectric layer and electrically connected to the electronic component and the electrically conductive posts through conductive vias. In one and more embodiments, the circuitry layer includes routing traces and a conductive paddle. The routing traces include the conductive vias for electrical connection with the electronic component (more specifically, the first contact pad of the top electrode layer of the electronic component) and the electrically conductive posts and provide horizontal routing. In the case of the second conductive island being present, the routing traces preferably have selected portions configured for interconnection with a semiconductor device superimposed over a top side of the second conductive island. The conductive paddle includes a first metallized recess that extends through the crack-inhibiting dielectric layer and contacts the top surface of the electronic component to provide conduction channels for heat passage and electricity (if required). More specifically, the first metallized recess of the circuitry layer may contact the second contact pad of the top electrode layer of the electronic component. Additionally, the interconnect board may further include a heat spreader attached to the first metallized recess through a soldering material to enhance the thermal performance.

Optionally, the circuitry layer may further include an additional conductive paddle for connection with the first conductive island. The additional conductive paddle includes a second metallized recess that extends through the crack-inhibiting dielectric layer and contacts the first conductive island to provide conduction channels for heat passage and electricity (if required). More specifically, the second metallized recess of the circuitry layer contacts the vertical segment of the first conductive island. As a result, the bottom electrode layer of the electronic component attached to the heat conduction surface of the first conductive island can be electrically connected to and thermally conductible with the circuitry layer through the second metallized recess. Likewise, the interconnect board may further include an additional heat spreader attached to the second metallized recess through a soldering material to enhance the thermal performance.

In the instance of a plurality of first conductive islands being included in the interconnect board, each of the conductive paddles may include both the first metallized recess and the second metallized recess, and each of the optional heat spreaders is attached to both the first metallized recess and the second metallized recess through the soldering material. As such, each of conductive paddles can provide an electrical connection between the top electrode layer of the n^{th} electronic component, attached to the n^{th} first conductive island (n being a positive integer), and the bottom electrode layer of the (n+1)th electronic component, attached to the (n+1)th first conductive island. This connection is made through the first metallized recess in contact with the n^{th} electronic component and the second metallized recess in contact with the (n+1)th first conductive island.

For further improved control of warpage, an additional crack-inhibiting dielectric layer may be applied below the first and second conductive islands and the electrically conductive posts as well as the stress-relief resin layer or the optional interfacial dielectric layer. Accordingly, simultaneous and symmetrical deposition of the top and bottom crack-inhibiting dielectric layers from above and below, respectively, is beneficial for enhanced warpage control. In this case, an additional circuitry layer is deposited below the bottom crack-inhibiting dielectric layer and connected to the first and second conductive islands and the electrically conductive posts.

In the manufacturing of the interconnect board, the crack-inhibiting dielectric frame is used instead of the conventionally used metal frame to create a plurality of distinct compartments. The top side of the crack-inhibiting dielectric frame may be substantially coplanar with the top sides of the electrically conductive posts. Compared to the commonly used metal frame, the crack-inhibiting dielectric frame typically has an elastic modulus lower than 50 Gpa and can reduce warpage caused by resin filling. Preferably, the crack-inhibiting dielectric frame is made from a filler-free organic material to prevent filler particles from contributing to the frame's susceptibility to cracking. More preferably, the crack-inhibiting dielectric frame is made of an organic material containing reinforcement configured to suppress crack propagation.

The present invention also provides an assembly (i.e. an embedded component assembly), in which one or more external components (e.g. semiconductor devices) are disposed above the crack-inhibiting dielectric layer and electrically connected to the circuitry layer of the above-mentioned interconnect board. For instance, one or more semiconductor devices may be face-down coupled to the circuitry layer using soldering materials in contact with the semiconductor devices and the circuitry layer. As a result, the semiconductor devices can be electrically connected to the electronic component embedded in the cavity of the interconnect board. In one or more embodiments, the semiconductor devices are superimposed over and thermally conductive with the single second conductive island or their respective second conductive islands. The semiconductor devices can be packaged or unpackaged chips. Furthermore, the semiconductor devices can be bare chips, or wafer level packaged dies, etc.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips.

The term “cover” refers to incomplete or complete coverage in a vertical and/or lateral direction and includes contact and non-contact situations. For instance, in a preferred embodiment, the stress-relief resin layer partially covers sidewalls of the electrically conductive posts, with their upper sidewalls completely covered by the stress-relief resin layer and lower sidewalls covered by the interfacial dielectric layer.

The term “surround” refers to relative position between elements regardless of whether the elements are spaced from or adjacent to one another. For instance, in a preferred embodiment, the stress-relief resin layer laterally surrounds the metallized segment with the adhesive between the stress-relief resin layer and the metallized segment.

The phrases “mounted over” and “attached on/to/onto” include contact and non-contact with a single or multiple element(s). For instance, in a preferred embodiment, the electronic component can be attached on the heat conduction surface of the first conductive island and is separated from the heat conduction surface by the adhesive.

The phrases “electrical connection” and “electrically connected” refer to direct and indirect electrical connection. For instance, in a preferred embodiment, the electronic component is electrically connected to the first conductive island by the electrically conductive adhesive but does not contact the first conductive island.

The spatially relative terms, such as “top”, “bottom”, “below”, “above”, “lower”, “upper” and the like, may be used herein for ease of description to describe one element or feature's relationship to another element(s) or feature(s) as illustrated in the figures. The spatially relative terms are intended to encompass different orientations of the interconnect board or assembly in use or operation in addition to the orientation depicted in the figures. For example, if the interconnect board or assembly in the figures is turned over, elements described as “below” other elements or features would then be oriented “above” the other elements or features, and “bottom” surfaces would become “top” surfaces. Thus, the example term “below” can encompass both an orientation of above and below. The interconnect board or assembly may be otherwise oriented (rotated 90 degrees or at other orientations) and the spatially relative descriptions used herein interpreted accordingly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. An interconnect board, comprising electrically conductive posts, a first conductive island, a stress-relief resin layer, an electronic component, a crack-inhibiting dielectric layer and a circuitry layer, wherein:
the first conductive island is spaced from the electrically conductive posts and has a heat conduction surface located at a level between top and bottom sides of the electrically conductive posts;
the stress-relief resin layer laterally covers sidewalls of the electrically conductive posts and laterally surrounds a cavity defined above the heat conduction surface of the first conductive island;
the electronic component is disposed within the cavity and superimposed over the heat conduction surface of the first conductive island;
the crack-inhibiting dielectric layer covers the top sides of the electrically conductive posts and top surfaces of the first stress-relief resin layer and the electronic component and extends into remaining spaces within the cavity; and
the circuitry layer is disposed on the crack-inhibiting dielectric layer and electrically connected to the electronic component and the electrically conductive posts through conductive vias.

2. The interconnect board of claim 1, wherein the first conductive island includes a metallized segment that has the heat conduction surface in contact with a bottom surface of the electronic component.

3. The interconnect board of claim 2, wherein the metallized segment is formed by electroplating onto a bottom electrode layer of the electronic component.

4. The interconnect board of claim 1, wherein the heat conduction surface is attached to a bottom surface of the electronic component using an adhesive between the heat conduction surface and the bottom surface of the electronic component.

5. The interconnect board of claim 1, further comprising an interfacial dielectric layer located underneath the stress-relief resin layer, wherein the stress-relief resin layer laterally covers upper portions of the sidewalls of the electrically conductive posts, and the interfacial dielectric layer laterally covers lower portions of the sidewalls of the electrically conductive posts as well as sidewalls of the first conductive island.

6. The interconnect board of claim 1, wherein the circuitry layer further includes a first metallized recess that extends through the crack-inhibiting dielectric layer and contacts the top surface of the electronic component.

7. The interconnect board of claim 6, further comprising a heat spreader attached to the first metallized recess through a soldering material.

8. The interconnect board of claim 1, wherein the electronic component has a bottom electrode layer in thermally conductible with the heat conduction surface of the first conductive island and electrically connected to a second metallized recess of the circuitry layer that extends through the crack-inhibiting dielectric layer and contacts the first conductive island.

9. The interconnect board of claim 8, wherein the second metallized recess of the circuitry layer contacts a vertical segment of the first conductive island, and the vertical segment has a top side substantially coplanar with the top sides of the electrically conductive posts.

10. The interconnect board of claim 1, wherein the stress-relief resin layer has an elastic modulus lower than that of the crack-inhibiting dielectric layer.

11. The interconnect board of claim 1, wherein the stress-relief resin layer has an elastic modulus lower than 30 Gpa.

12. The interconnect board of claim 1, wherein the stress-relief resin layer is an organic material with electrically insulative fillers.

13. The interconnect board of claim 12, wherein the electrically insulative fillers have a CTE less than 20 ppm.

14. The interconnect board of claim 1, wherein the crack-inhibiting dielectric layer is an organic material with a reinforcement configured to suppress crack propagation.

15. The interconnect board of claim 1, further comprising a second conductive island spaced from the first conductive island and from the electrically conductive posts and having an upper sidewall portion covered by the stress-relief resin layer.

16. The interconnect board of claim 15, wherein the circuitry layer has selected portions configured for interconnection with a semiconductor device superimposed over a top side of the second conductive island.

17. The interconnect board of claim 1, further comprising a crack-inhibiting dielectric frame configured with at least one inner periphery each located around a compartment and laterally covered by the stress-relief resin layer, wherein the electrically conductive posts, the first conductive island, the stress-relief resin layer and the electronic component are accommodated within the compartment.

18. The interconnect board of claim 17, wherein the crack-inhibiting dielectric frame has an elastic modulus lower than 50 Gpa.

19. The interconnect board of claim 17, wherein the crack-inhibiting dielectric frame is an organic material with a reinforcement configured to suppress crack propagation.

20. The interconnect board of claim 17, wherein the crack-inhibiting dielectric frame has an elastic modulus greater than that of the stress-relief resin layer.
